(19) United States
(12) Patent Application Publication
(10) Pub. No.: US 2003/0006762 A1
(43) Pub. Date: Jan. 9, 2003

(54) Surgical sponge and detection system therefor

(76) Inventor: Philip E. Clements, Littleton, CO (US)

Correspondence Address: John L. Isaac, Esq., Isaac & Associates, Suite 900, 143 Union Blvd., Lakewood, CO, 80228-1829, US

(21) Appl. No.: 09/899,460

(22) Filed: Jul. 6, 2001

(51) Int. Cl. G01N 27/72; G01R 33/12

(52) U.S. Cl. 324/239

(57) ABSTRACT

A surgical sponge is provided and adapted to prevent unaccounted disposal thereof. The sponge includes an absorbent pad and a visually identifiable member attached to the pad. The visually identifiable member assists in identification and accounting in a surgical environment. Finally, a metallic tag of sufficient size is incorporated with the sponge to provide detection by a metal detector device upon disposal of the sponge.

### RELATED APPLICATIONS

This is related to U.S. Pat. No. 5,659,247 issued Aug. 19, 1997, U.S. Pat. No. 5,576,621 issued Nov. 19, 1996 and U.S. Pat. No. 6,222,450 issued Apr. 24, 2001, the contents of which are specifically incorporated herein by reference.

### BACKGROUND OF THE INVENTION

1. Field of the Invention

This invention relates generally to surgical sponges and apparatus for the accounting thererof during and after surgical procedures. More particularly, the present invention relates to improved surgical sponges adapted for use with a metal detector system designed to detect the inadvertent disposal of objects, such as surgical instruments, into receptacles and which are particularly useful in medical facilities and the like. Specifically, the present invention relates to improved surgical sponges and systems therefor arranged to prevent the disposal of such sponges without being accounted for.

2. Description of the Prior Art

One of the major problems in the health care industry today is the high cost of patient care. While many factors contribute to this cost, one of these factors is the difficulty in controlling waste as well as unnecessary surgical procedures in a hospital environment. In the operating room, surgical instruments are inadvertently but routinely discarded along with disposable drapes, gowns, sponges and the like after an operation. These expensive instruments are intended for reuse, and their disposal represents a substantial waste. Moreover, these instruments as well as surgical dressings and sponges utilized during an operation must be carefully accounted for in order to avoid a potentially time-consuming and difficult search including the possibility of opening up a patient's sutured area to find any missing items.

Moreover, used disposable surgical drapes, gowns, sponges and the like, are generally deposited in a large receptacle bag approximately the size of a lawn and garden trash and leaf bag designated for such waste. These bags are held for use in an open position in each operating room by a bag holder, typically in the form of a wheeled cart. Hospital personnel merely wad up used drapes and gowns and stuff them into the receptacle bag for disposal. Sponges are also similarly discarded after they have all been accounted for. As can be readily appreciated, valuable surgical instruments as well as sponges can easily become bundled with the used drapes and gowns, and disposed inadvertently or otherwise.

It is important in a surgical environment that instruments, dressings and sponges be accounted for in order to prevent the possible situation wherein they remain inside a patient after closure and suturing. There are numerous known prior art devices and methods available for keeping track of as well as detecting surgical implements including instruments and sponges. Some of these are designed for detecting the surgical implements if left inside a patient, while others are designed to provide an accounting scheme designed to insure that all implements are accounted for before suturing the patient. Some of the systems are passive in nature while others require elaborate and expensive active sensors or other detection devices. Examples of these include the U.S. Pat. No. 4,193,405, No. 4,658,818 and No. 5,923,001. Moreover, U.S. Pat. No. 4,903,837, No. 5,650,596 and No. 5,078,569 all disclose systems whereby sponges, needles and the like are coded in an accounting display and/or system so that their absence becomes evident prior to patient closure.

Metal detectors of various types are also well known in the art. U.S. Pat. No. 5,001,425 discloses a device designed to cover a receptacle for use in a hospital environment to detect the inadvertent disposal of metal articles in such a receptacle. As is pointed out therein, however, a significant problem in a hospital environment, and in particular surgical environments, is the presence of numerous metal objects surrounding the receptacle. Such metal objects proximate the detector can cause the inadvertent triggering of the detector alarm system without a metallic article having actually been placed therein due to false readings from metal articles immediately surrounding or near the top of such a receptacle. The devices illustrated in the above-identified related U.S. Pat. No. 5,659,247, No. 5,576,621 and No. 6,222,450 are designed to avoid these problems. However, these devices are specifically designed and envisioned for use to prevent the inadvertent disposal of larger surgical instruments. Non-metallic items, or metallic items which are quite small, which are used in surgery, and in particular surgical sponges, are not detected by such devices. Nonetheless, these items, like the surgical instruments, must be accounted for and may not be left inside a patient.

Previously, systems were provided to routinely screen and detect retained surgical materials in the bodies of human patients while still under anesthesia and on the operating room table prior to the surgical wound closure. These procedures are time-consuming and expensive. Moreover, after-the-fact detection tags and systems cause substantial expense and tremendous liability problems. Thus, there remains a need for surgical sponge designs and systems that obviate such post surgical processes without requiring expensive active tags and sensors. The present invention satisfies this need.

### SUMMARY OF THE INVENTION

Accordingly, it is one object of the present invention to provide an improved surgical sponge adapted for easy accounting in a surgical environment.

It is another object of the present invention to provide an accounting system for surgical sponges and the like that takes advantage of existing monitor devices.

Yet another object of the present invention is to provide an improvement to surgical sponge design that prevents them from being inadvertently discarded in a surgical environment without being accounted for.

To achieve the foregoing and other objects and in accordance with the purpose of the present invention, as embodied and broadly described herein, a surgical sponge is provided and adapted to prevent unaccounted disposal thereof. The sponge includes an absorbent pad and a visually identifiable member attached to the pad. The visually identifiable member assists in identification and accounting in a surgical environment. Finally, a metallic tag of sufficient size is incorporated with the sponge to provide detection by a metal detector device upon disposal of the sponge.

In one form of the invention, the visually identifiable member is color-coded and is in the form of a tail element attached to and extending outwardly from the pad. In another form, the metal tag is made from metal foil and is disposed in or along the color-coded identification tail element.

Still another form of the invention includes an apparatus and system which accounts for surgical sponge usage and location in a surgical environment. The apparatus includes a disposal receptacle for receiving used surgical materials and other disposable articles used in a surgical environment. A metal detection device is then provided for detecting the passage of selected articles therethrough into the receptacle. Finally, surgical sponges are provided each having an absorbent pad, a color coded identification element extending outwardly from the pad, and a metallic tag disposed within the identification element of sufficient size to trigger the metal detection device when passed therethrough into the disposal receptacle.

Yet another aspect of the invention is in the form of an improvement to a detection system to account for non-metallic surgical implements, sponges and articles utilized in a surgical environment. The system includes a receptacle to receive disposable materials, and a metal detection apparatus mountable over the receptacle to detect the inadvertent disposal of metallic surgical instruments into the receptacle. The improvement is provided wherein the implement includes a color-coded identification element extending outwardly therefrom, and a metallic tag disposed within the identification element of sufficient size to trigger the metal detection apparatus when passed therethrough into the receptacle.

### BRIEF DESCRIPTION OF THE DRAWINGS

The accompanying drawings which are incorporated in and form a part of the specification illustrate a preferred embodiment of the present invention and, together with a description, serve to explain the principles of the invention. In the drawings:

FIG. 1 is a front perspective view of a surgical sponge adapted in accordance with the present invention; and

FIG. 2 is a side perspective view of a metal detection device utilized in a surgical environment for detecting the inadvertent disposal of instruments in accordance with the related references cited above and incorporated herein by reference.

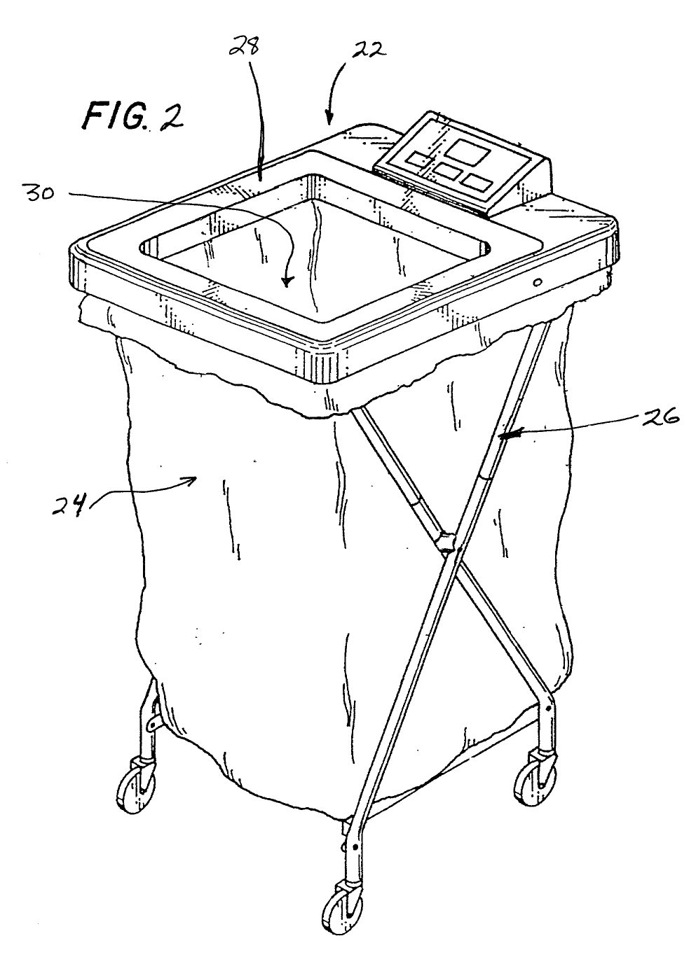

### DETAILED DESCRIPTION OF THE PREFERRED EMBODIMENTS

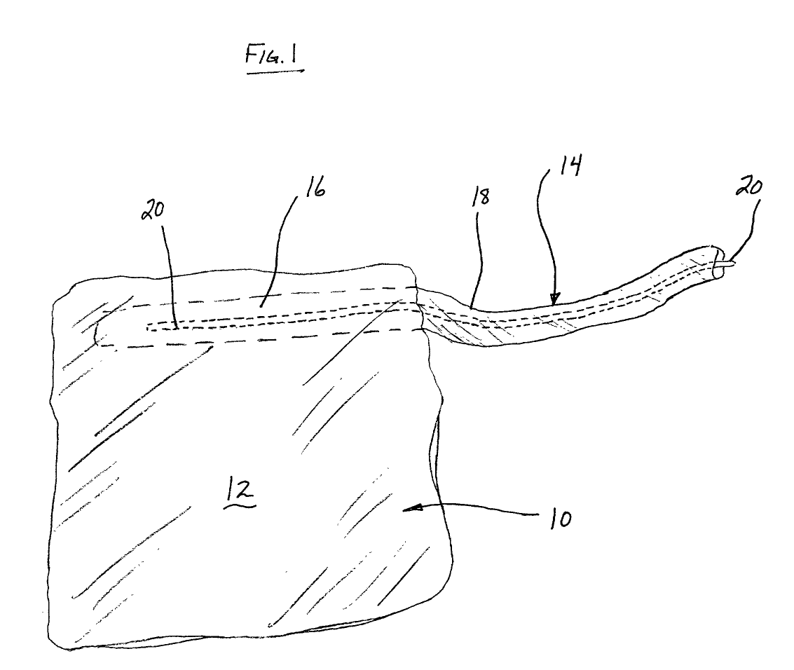

Referring now to FIG. 1, a surgical sponge 10 is illustrated and includes a nonmetallic absorbent pad 12. An elongated visually identifiable member 14 is secured to the pad 12 and extends preferably outwardly therefrom. It should be understood, however, that any essentially nonmetallic implement, such as a dressing, needles and the like, can be utilized with the present invention. In this instance, the visually identifiable member 14 may be attached to the implement in a manner similar to its attachment to the pad 12.

As can be seen from FIG. 1, the interior end 16 of the member 14 is preferably attached within the pad 12 utilizing any known means such as stitching or glue. The outwardly extending portion 18 projects a distance from the pad 12. The outward portion or arm 18 is preferably brightly color-coded in a color contrasting with the colors typically found in a body cavity of a patient. Such colors may include yellow, orange, lavender, green and the like. This provides two primary benefits. First, when the sponge 10 is placed within the body cavity of a patient, for example, so that the pad 10 becomes absorbed in blood and other bodily fluids, the color of the outer end arm 18 can still be readily seen since it is contrasted with the fluid and tissue colors of the patient. Moreover, the colors utilized with the outer end portion 18 may also be color matched or coordinated to a box container or other holder to permit easy counting to determine the absence of any sponge or implement 10 after the surgery is complete.

However, mere color coding of tagged or other identifying elements associated with the sponge or other implement 10 by itself is still insufficient. This is due to the fact that while the color contrast may make the sponges easier to identify within the body cavity of a patient, or the absence of the proper number of sponges according to the color coordinated container would indicate a lack of accounting of all the sponges, this still does not help in determining the location of any missing sponges. Thus, if a patient's wound is closed and then the number of sponges found to be inaccurate, the patient may still need to be opened up again to further look for the missing sponges or other components.

To obviate the above problem without using expensive active sensors as in the prior art, the sponge or implement 10 of the present invention further includes a metallic tag 20 associated with the visually identifiable member 14 and the pad 12. Prior to my metal detector inventions referenced above and incorporated herein by reference, such metal tags would not be particularly helpful in the process of accounting for all the sponges or implements 10 as well as locating any that appear to be missing. However, the metal detector 22 of my prior patents include a receptacle bag 24 as typically utilized in a surgery environment, a movable tubular support structure 28 for the receptacle bag 24, and a metal detector device 28 disposed over the opening 30 of the bag 24. The metal detector device 28 is designed to detect the passage of significant metal members through the opening 30 into the bag 24, primarily to prevent the inadvertent disposal of expensive surgical instruments. However, this metal detection system may be utilized with the sponge design of my present invention.

Since a primary objective of the present invention is to the eliminate the need of opening up a patient's wound after suturing it closed in order to locate any missing implements such as sponges, dressings, needles and the like, a preferred accounting system would include a mechanism whereby any such nonmetallic items inadvertently and unintentionally discarded into a receptacle bag would automatically be accounted for. In this manner, when other accounting systems, such as visual identification and color coding arrangements, determine the absence of one or more such implements, it no longer becomes necessary to open up a patient under the assumption that it has been left therewithin. Moreover, it will no longer becomes necessary to physically search the infectious waste bags to locate any missing sponges and the like.

To accomplish this purpose, the metal tag 20 is incorporated into the sponge 10 preferably by physically disposing it within the elongated visually identifiable member 14. In most preferred form, the metallic tag 20 is a metal foil preferably in the form of a foil string extending substantially along the length of the member 14. The metal tag 20 is of sufficient size so that it will trigger the metal detector 28 if passed therethrough. In this manner, if the sponge 10 is inadvertently disposed within the receptacle 24 without first accounting for it, the detector 28 will be triggered so as to thereby account for the discarded sponge 10. If several such sponges are discarded in this manner, the detector 28 will indicate their disposal and thus account for such missing items. After the surgical procedure is complete, the remaining sponges 10 may be counted and identified by their color coded identifiable element 14, and this number may then be added to the number detected by the device 28. If in this instance, there remains a sponge or implement 10 that is missing, the odds become substantially greater that it has in fact been left within the patient, and x-rays may then be taken to detect the metal tag contained in the implement or sponge 10. Alternatively, a metal detector wand similar to those presently used with airport security could be moved over the patient to determine the presence of a metal tagged sponge within the patient rather than exposing the patient to possibly unnecessary as well as costly and time consuming x-rays.

It should be clear from the above description that the present invention provides a combination technique and system using both visual identification elements as well as metal tags to more accurately determine the disposition and location of any discarded, substantially nonmetallic surgical implements such as sponges, dressings and the like. The present invention is inexpensive to manufacture and implement and is utilized with a now existing metal detection device and system which was originally designed not for nonmetallic surgical implements, but rather for the prevention of inadvertent disposal of expensive surgical instruments. The present invention will substantially reduce hospital surgical expenses by providing a simple device and system for accounting for sponges and other surgical implements discarded during and after surgery. Moreover, the present invention will significantly reduce the likelihood of postoperative procedures whereby the patient's wound must be re-opened to search for missing implements or surgical materials. This will also significantly reduce the expense of hospital surgical procedures as well as the liability exposure from unnecessary and perhaps even negligent surgical procedures.

The foregoing description and the illustrative embodiments of the present invention have been described in detail in varying modifications and alternate embodiments. It should be understood, however, that the foregoing description of the present invention is exemplary only, and that the scope of the present invention is to be limited to the claims as interpreted in view of the prior art. Moreover, the invention illustratively disclosed herein suitably might be practiced in the absence of any element which is not specifically disclosed herein.

I claim:

1. A surgical sponge adapted for preventing unaccounted disposal thereof, said sponge comprising an absorbent pad, a visually identifiable member attached to said pad to assist in identification and accounting in a surgical environment, and a metallic tag of sufficient size to provide detection by a metal detector device upon disposal of said sponge.

2. The surgical sponge as claimed in claim 1, wherein said visually identifiable member comprises a tail element extending outwardly from said pad.

3. The surgical sponge as claimed in claim 2, wherein said tail element is elongated and color coded for identification and accounting purposes.

4. The surgical sponge as claimed in claim 1, wherein said metallic tag comprises metal foil.

5. The surgical sponge as claimed in claim 4, wherein said metal foil tag is disposed in said visually identifiable member.

6. The surgical sponge as claimed in claim 5, wherein said visually identifiable member comprises a tail element extending outwardly from said pad with said foil tag disposed therein.

7. The surgical sponge as claimed in claim 6, wherein said tag comprises a metal foil string disposed in said elongated tail element.

8. A surgical apparatus to account for surgical sponge usage and location in a surgical environment, said apparatus comprising:
a disposal receptacle for receiving used surgical materials and other disposable articles used in a surgical environment;
a metal detection device for detecting the passage of selected articles therethrough into said receptacle; and
a surgical sponge having an absorbent pad, a color coded identification element extending outwardly from said pad, and a metallic tag disposed within said identification element of sufficient size to trigger said metal detection device when passed therethrough into said receptacle.

9. The surgical apparatus as claimed in claim 8, wherein said identification element comprises a tail element attached to and extending outwardly from said pad.

10. The surgical apparatus as claimed in claim 8, wherein said metallic tag comprises metal foil.

11. The surgical apparatus as claimed in claim 10, wherein said metal foil tag is disposed in said color-coded identification element.

12. The surgical apparatus as claimed in claim 11, wherein said color-coded identification element comprises a tail element attached to and extending outwardly from said pad.

13. The surgical apparatus as claimed in claim 12, wherein said tag comprises a metal foil string disposed in said elongated tail element.

14. In a detection system to account for non-metallic surgical implements and sponges utilized in a surgical environment including a receptacle to receive disposable materials, and a metal detection apparatus mountable over the receptacle to detect the inadvertent disposal of metallic surgical instruments into said receptacle, the improvement wherein said surgical implements comprise a color coded identification element extending outwardly therefrom, and a metallic tag disposed within said identification element of sufficient size to trigger said metal detection apparatus when passed therethrough into said receptacle.

15. The improvement as claimed in claim 14, wherein said implement comprises a surgical sponge having an absorbent pad, and said color-coded identification element extends outwardly from said pad.

16. The improvement as claimed in claim 14, wherein said color coded identification element comprises a tail element attached to and extending outwardly from said implement.

17. The improvement as claimed in claim 16, wherein said metallic tag comprises metal foil.

18. The improvement as claimed in claim 17, wherein said metal foil tag is disposed in said color-coded identification tail element.

19. The improvement as claimed in claim 18, wherein said metal foil tag comprises a metal foil string disposed along the length of said elongated identification tail element.

20. The improvement as claimed in claim 19, wherein said implement comprises a surgical sponge having a non-metallic absorbent pad, and said tail element and foil tag are attached to and extend outwardly from said pad.
